(19) United States
(12) Patent Application Publication
(10) Pub. No.: US 2011/0253200 A1
(43) Pub. Date: Oct. 20, 2011

(54) REFLECTIVE TANDEM SOLAR CELL

(75) Inventors: Max Shtein, Ann Arbor, MI (US); Kevin P. Pipe, Ann Arbor, MI (US); Brendan T. O'Connor, Raleigh, NC (US); Denis Nothern, Ann Arbor, MI (US)

(73) Assignee: THE REGENTS OF THE UNIVERSITY OF MICHIGAN, Ann Arbor, MI (US)

(21) Appl. No.: 13/087,665

(22) Filed: Apr. 15, 2011

Related U.S. Application Data
(60) Provisional application No. 61/324,497, filed on Apr. 15, 2010.

(51) Int. Cl. H01L 31/048; H01L 31/042

(52) U.S. Cl. 136/251; 136/244

(57) ABSTRACT

A novel solar cell architecture consisting of multiple fiber-based photovoltaic (PV) cells. Each PV fiber element is designed to maximize the power conversion efficiency within a narrow band of the incident solar spectrum, while reflecting other spectral components through the use of optical microcavity effects and distributed Bragg reflector (DBR) coatings. Combining PV fibers with complementary absorption and reflection characteristics into volume-filling arrays produces an array of spectrally tuned solar cells with an effective dispersion element intrinsic to the architecture, resulting in high external quantum efficiency over the visible spectrum.

### CROSS-REFERENCE TO RELATED APPLICATIONS

This application claims the benefit of U.S. Provisional Application No. 61/324,497, filed on Apr. 15, 2010. The entire disclosure of the above application is incorporated herein by reference.

### GOVERNMENT INTEREST

This invention was made with government support under Grant Nos. FA9550-06-1-0399 and FA9550-09-1-0109 awarded by the Air Force Office of Scientific Research. The government has certain rights in the invention.

### FIELD

The present disclosure relates to solar cells and, more particularly, to tandem solar cells.

### SUMMARY

This section provides a general summary of the disclosure, and is not a comprehensive disclosure of its full scope or all of its features.

According to the principles of the present teachings, a solar cell is provided having broad-band, efficient absorption of sunlight accomplished by means of combining sub-cells which are individually absorbing over a narrower, but complementary spectral bands. There may be multiple sub-cells having overlapping absorption spectra. The sub-cells may also be coated with optical filters/reflectors having transmission and reflection characteristics correlated with the absorption bands of the sub-cells. The sub-cells are distributed in 3-dimensional space.

Spectral selection for each sub-sub-cell can be accomplished by some common wavelength selection means. These means can include, for example, use of an optical microcavity based on the electrode-semiconductor-electrode stack, or a distributed Bragg reflector coating the sub-subcell, a 2- or 3-dimensional photonic crystal, or a combination of these.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 depicts tandem solar cell designs including (a) a traditional transmissive solar cell design, (b) a reflective tandem solar cell in a v-shape configuration, and (c) an example of a reflective fiber based tandem cell design consisting of three rows of three spectrally tuned photovoltaic sub-cells. The fiber OPV cells consist of a distributed Bragg reflector (DBR), a thick spacer layer, the transparent top electrode, the active organic layers, and finally an optically thick center electrode.

FIG. 2 depicts the device structures modeled for a single solar cell structures. (a) A planar metal-organic-metal solar cell, (b) a fiber OPV cell geometry, (c) a row of fibers, and (d) a matrix of fiber cells. (e) The generic structure for the solar cell in all configurations.

FIG. 3 depicts output of the ray-tracing program that is used to analyze periodic multi-fiber OPV systems. Sample rays are traced to visually inspect the performance of the bundled fiber OPV system. Rays that leave the system are shown in green, and rays that intersect at least two bodies are shown in blue.

FIG. 4 depicts the dependence of the reflectivity on incident light angle for the metal-organic-metal solar cell with the absorption band of the active layer between 500-700 nm. For a single row of adjacent fibers, incident light beyond a certain angle (e.g. 40 degrees will reflect off the fiber OPV cell and be incident upon an adjacent fiber.

FIGS. 5(a)-(d) depict 2-dimensional coordinates for well-performing fiber-OPV bundles for 1, 2, 3, and 10-row systems. The coordinates are given in terms of fiber diameters.

FIG. 6 depicts the predicted short circuit current for the fiber bundles ranging from a single stand alone fiber, to a fiber system consisting of 20 rows. The coordinates for the 1, 2, 3 and 10 row systems are given in FIG. 5 (but can vary from these in other instances). The number of sub-cells is also varied from 1 to 4 designs. The exact structure of the OPV sub-cells is dependent on the spectral band being optimized, and is based on maximizing the external quantum efficiency of the cell in a planar configuration. As a comparison, the single sub-cell type is compared to a similar OPV cell based on a planar heterojunction structure consisting of CuPc and C60 as the donor-acceptor materials.

FIG. 7 depicts performance parameters for the 10-row, 4 color-tuned OPV fiber bundle. (a) The external quantum efficiency (EQE) of the planar counterpart of the 4 microcavity tuned OPV cells under normal illuminations. The reflectivity of one of the cells is also given illustrating the high reflectivity for off-resonant wavelengths. (b) The total EQE along with contribution of the separate color-tuned fibers in the 10-row, 4 color-tuned bundle. The open circuit voltage is also given for each subcell, assuming optimistic but realistic parameters of the organic materials constituting the active layers, used here as an example for predicting efficiency.

FIG. 8 depicts the angular dependence of a planar metal-organic-metal OPV device and a 2-row fiber bundle having the same cell design. Also plotted is the performance of the 10-row, 3 color-tuned fiber bundle with the layout given in FIG. 5. The variation in the incident angle for the bundle is illustrated in FIG. 1c. The 10-row fiber bundle is asymmetric and the performance is therefore given for 3-angle variations. The relative responsivity is a measure of performance assuming the intensity on the surface of the top face of the solar cell is constant with angle.

FIG. 9a is a schematic perspective view of a solar cell system having rigid cells and modules according to the principles of the present teachings.

FIG. 9b is a top view of the solar cell system of FIG. 9a.

FIG. 9c is a side view of the solar cell system of FIG. 9a.

FIG. 10 is a schematic perspective view of a solar cell system having flexible cells and modules according to the principles of the present teachings.

Corresponding reference numerals indicate corresponding parts throughout the several views of the drawings.

### DETAILED DESCRIPTION

Example embodiments will now be described more fully with reference to the accompanying drawings. Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

### I. INTRODUCTION OF THE FIBER BASED OPV TANDEM CONCEPT

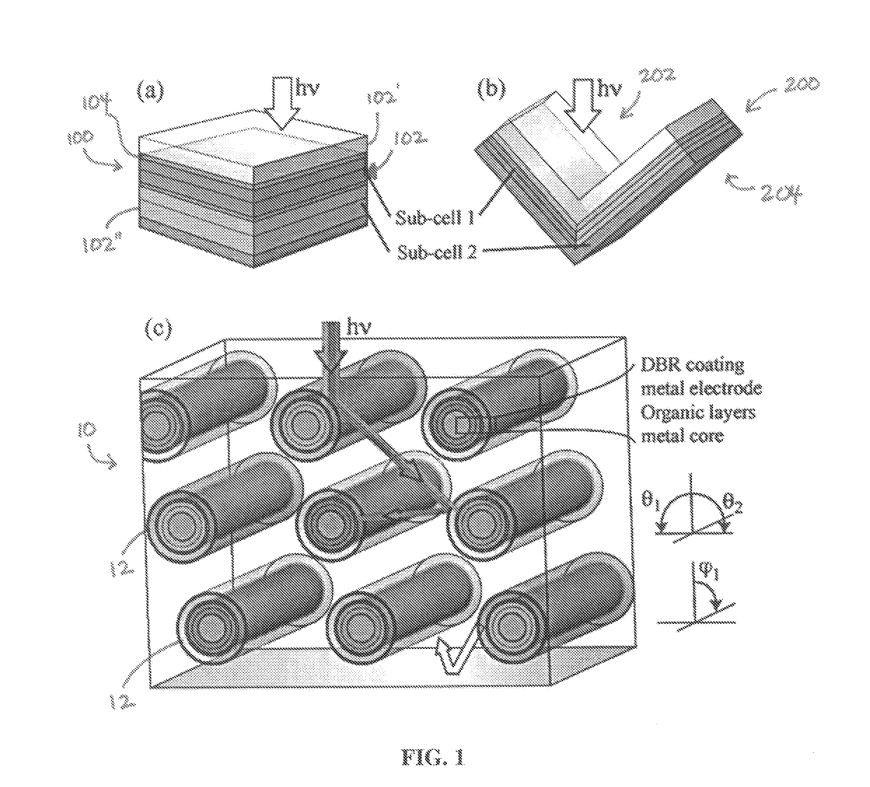

One way to improve photovoltaic power conversion efficiency in an attempt to approach and supersede the Shockley-Queisser limit is to employ several solar cells in tandem, with different bandgaps covering complementary parts of the solar spectrum, reducing thermalization losses and increasing the cell voltage. Organic tandem solar cells have been considered in two main configurations (shown schematically in FIGS. 1a and 1b)—transmissive 100 (see FIG. 1a) and reflective 200 (see FIG. 1b). In the more common transmissive configuration 100, multiple sub-cells 102 are stacked, such that whatever spectral components aren't absorbed in the front cell 102′ are potentially absorbed by the back cell(s) 102″. The sub-cells are typically connected in series, for example by placing a recombination electrode 104 between them. In this configuration, the layer thicknesses and composition are optimized by combining optical and transport models, subject to the restriction that the photocurrent from each sub-cell must be matched. This restriction can be a limiting factor in terrestrial applications.

Alternatively, as seen in FIG. 1b, two sub-cells units 202, 204 can be placed next to each other at an angle (forming a “V” profile), such that incident light (hv) that is not absorbed by one sub-cell 202 is reflected onto and potentially captured by the opposing sub-cell 204. At very sharp angles of the “V” the incident light can trapped efficiently. However, this design is limited to two complementary sub-cells and the intensity distribution along the sub-cell length is highly uneven (particularly at sharp V angles). Due to typical variation in open circuit voltage (V_{OC}) and the fill factor (FF) of organic solar cells with illumination intensity, this latter effect may potentially make it difficult to find the optimal power point of the cell.

A novel tandem solar cell architecture 10 according to the principles of the present teachings is provided, illustrated schematically in FIG. 1(c), based on a collection of efficient narrow-band absorbing sub-cells 12, whose cumulative response can be made efficient over a broad incident spectrum by engineering efficient reflection of off-resonance spectral components among the constituent sub-cells. Such architectures 10 can be realized in the form of arrays of fiber-shaped solar cells, distributed throughout a volume. This arrangement can be achieved, for example, by 3-dimensional weaving and/or by embedding solar cell fibers in a clear polymer matrix. We describe the details of several promising arrangements and calculate their expected performance based on experimentally validated optical and transport models of organic solar cells and optical coatings. Realistic materials combinations and geometries are calculated to yield performance significantly exceeding the state-of-the-art in organic PV cells.

The present teachings are organized as follows. First, we discuss general considerations for designing a volumetrically-distributed, internally-dispersive tandem solar cell using color-tuned fiber sub-cells. Then, we discuss the simulation framework used for modeling and optimizing the performance of individual solar cells, followed by a discussion of the array optimization. Using this framework, we first consider the performance of an array comprised of fibers, which all have identical cell structure optimized for absorption efficiency. To demonstrate the advantage of the tandem solar cell concept, we then consider the performance of an array comprised of color-tuned fibers, which incorporate narrow-band dielectric filters/reflectors, showing that the architecture can lead to high overall power conversion efficiency.

### II. DESIGN OF SINGLE FIBER OPV CELL AS CONSTITUENT OF 3-DIMENSIONAL REFLECTIVE TANDEM DESIGN

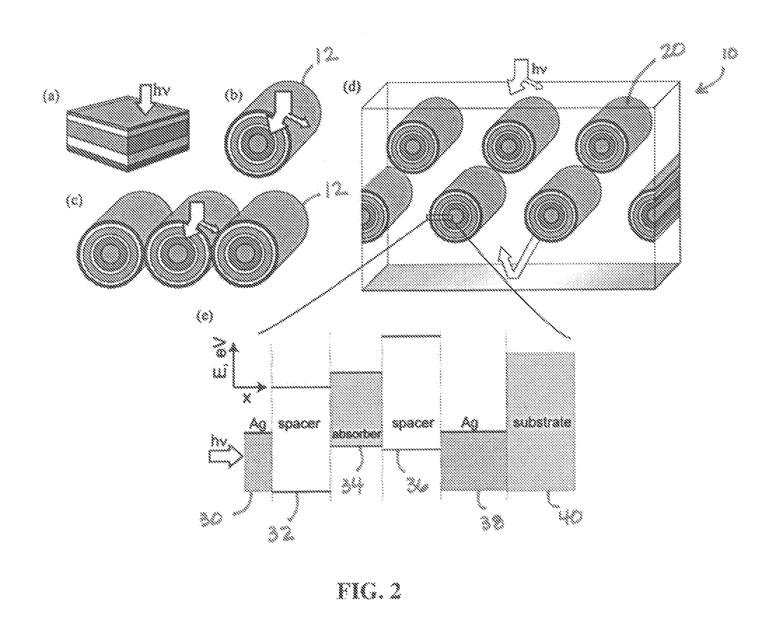

Several variants of fiber based PV cells have been demonstrated, particularly those using organic semiconductors deposited on non-planar substrates. Here, as seen in FIG. 2b, we utilize a simple heterojunction OPV cell 20 consisting of a metal-organic-metal layer sequence deposited onto a fiber substrate (FIG. 2b) rather than a planar substrate (see FIG. 2a). That is, a fiber core 22 having a first metal layer 24 deposited thereon, an organic layer 26 deposited on the first metal layer 24, and a second metal layer 26 deposited on the organic layer 26. This device structure, arranged in a matrix or array configuration 10 (see FIG. 2d), allows light hv to enter the organic photovoltaic (OPV) cell 20 radially from the outside, opposite the substrate, unlike in typical planar cells that are fabricated on glass. Additionally, the metal-organic-metal layer configuration can be designed to form a strong optical microcavity that can be tuned to efficiently absorb light over a narrow part of the spectrum. It should be appreciated that the matrix 10 can define any number of rows, columns, and offset, such as two rows (FIG. 2d), three rows (FIG. 1c), and the like.

The motivation for using a metal-organic-metal layer structure instead of a traditional configuration employing ITO is two-fold: a) eliminating ITO potentially improves manufacturability, reliability, and cost-effectiveness; and b) it allows for a stronger optical microcavity that can be tuned to efficiently absorb light over a narrower part of the spectrum.

The individual OPV cells 20 considered here (FIG. 2e) comprise a semitransparent silver cathode 30, an optical spacer 32 (working simultaneously as a charge transport layer), an active absorbing layer 34, another optical spacer 36 (doubling as an exciton blocking layer), an optically thick silver electrode 38 built upon a substrate 40 (listed in the order of each layer's position in the path of an incident photon). Numerous commercially available organic dye molecules can be identified to cover 200 nm or more with a high coefficient of absorption (i.e. >1.5×10⁵ cm⁻¹) within the 300-1000 nm spectral range. To simplify the initial study, we do not use specific materials for the absorber but assume a material capable of absorbing over a 200 nm optical bandwidth between 300-1000 nm. The real part of the refractive index of the absorber is set to, n=1.75, and the extinction coefficient, k=λα/4π over the 200 nm absorption band and k=0 at all other wavelength, where λ is the wavelength of light and the absorption coefficient, a=1.5×10⁵ cm⁻¹. A nominal exciton diffusion length (L_{D}) of 20 nm is also assumed for this layer. The refractive index of the remainder of the cell includes 1.75 for the optical spacers and a wavelength-dependent value for silver taken from literature. The thickness of the semitransparent top electrode is set to 10 nm, and the thickness of the back electrode is set to 100 nm. A 10 nm Ag film has been shown to have a sheet resistance comparable to indium tin oxide making it a suitable alternative transparent conducting electrode. Finally the thicknesses of the optical spacers and absorption layer are designed to maximize the short circuit current, j_{SC}, of the individual OPV cell 20.

### III. APPROACH TO MODELING AND OPTIMIZATION OF INDIVIDUAL FIBER OPV CELLS AND MULTI-FIBER ARRAYS

The design and analysis of the fiber OPV cells 20 is studied using optoelectronic models presented and validated in detail elsewhere. Briefly, the model allows us to quantify the optical field intensity distribution throughout the OPV cell using the transfer matrix approach. From the optical field intensity distribution the exciton generation rate is calculated, followed by numerically solving an exciton diffusion equation to determine the external quantum efficiency (η_{EQE}). The boundary conditions for the diffusion equation are: 1) complete exciton dissociation at the boundary between the electron donor and acceptor layers (here, the absorber and front side optical spacer), and 2) zero exciton diffusion at the opposing boundary (i.e. absorber/back side optical spacer). Following exciton dissociation, 100% charge collection efficiency at the electrodes is assumed. A qualitative view of a flat-band energy level structure for this cell configuration is given in FIG. 2e. The j_{SC} is then predicted by integrating the product of η_{EQE} and incident photon flux over the solar spectrum (AM1.5G, truncated between 300-1000 nm).

To model the OPV cell on a fiber substrate, we consider it to be a collection of vanishingly small planar cells tangentially distributed along the circumference of the fiber, each having light rays incident at an arbitrary angle through a 180-degree range. This approach has been used to accurately model organic solar cells in many studies, including those that consider the dependence on illumination angle. Other key parameters of OPV cell performance include the fill factor (FF), and open circuit voltage (V_{OC}). The V_{OC} of each cell is set to be 0.4 V less than the potential given by the optical bandgap (roughly the HOMO-LUMO gap) of the absorbing material. The FF is assumed to be 0.7, a value that is observed in high performance OPV cells.

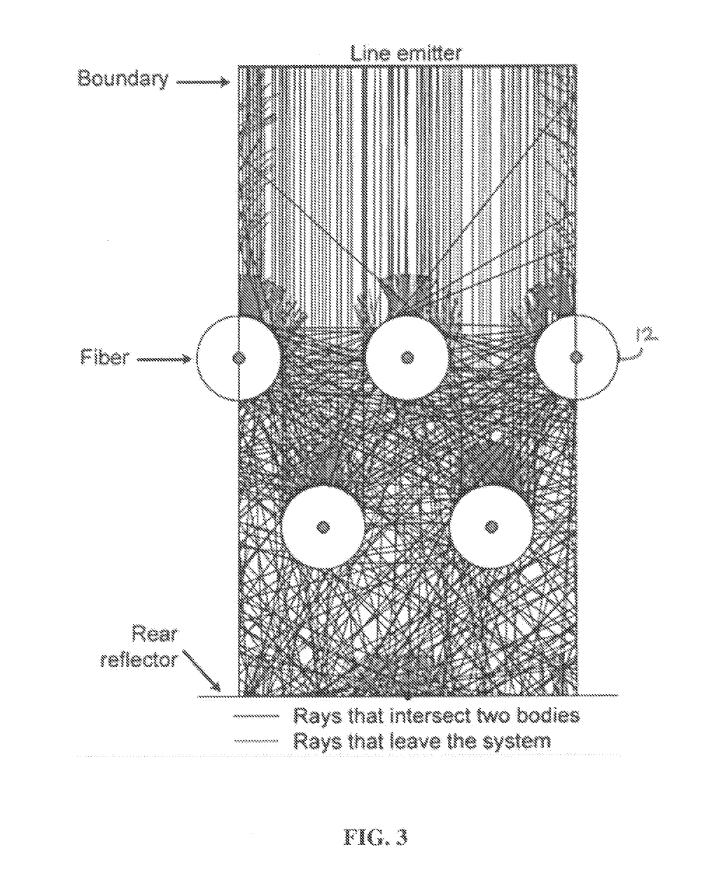

To evaluate multi-fiber OPV systems, such as those of the present teachings, the cell model embodying an individual fiber OPV cell is combined with numerical ray-tracing. A multi-fiber unit cell is first constructed in which each fiber is assumed to be infinitely long. The location of each fiber within the unit cell is specified, and periodic boundary conditions are applied in the direction normal to the fiber axis, such that the array extends “horizontally”. A line emitter, defined above the fiber system, emits light rays towards the fiber bundle. A retro-reflector (with reflectivity=1) is placed below the fiber bundle. As depicted in FIG. 3, a random sample of rays is traced for a two-row fiber OPV matrix 10. In this simulation, rays incident on the left or right edge of the unit cell are translated to the opposite edge in order to satisfy the periodic boundary condition. On average the rays strike all surfaces of each fiber, suggesting that shading losses are negligible. The ray-tracing routine is carried out until the summed intensity of the rays remaining in the array is less than 0.5% of the input intensity. For the line emitter, 10,000 rays are generated (20,000 rays in the case of bundles with 20 rows of fiber cells) and randomly placed along the length of the emitter with even probability, resulting in a standard deviation of the predicted j_{SC} for repeated simulations of the larger bundles of less than 0.094 mA/cm² (based on the area occupied by the entire array—i.e. “real estate” of the module).

A key aspect of the multi-fiber tandem design of the present teachings is that those incident wavelengths that are not efficiently harvested by a given fiber 20 are efficiently reflected. An appropriately tuned metal-organic-metal cavity reflects a large portion of the off-resonant light. However, due to the large number of reflections experienced by a light ray on average, even a small amount of parasitic absorption in the outer electrode for a single pass can escalate to a substantial loss overall. Therefore, we further improve off-resonant reflectivity by applying dielectric coatings around the OPV fiber 20. A 30-layer dielectric coating is applied to the color-tuned OPV cells with an initial design based on multiple quarter wave stacks of 5-10 layers, forming a band pass filter. Each quarter wave stack gives rise to regions of high reflectivity around its characteristic wavelength; combining several stacks forms regions of high reflectivity for spectral components that are off-resonance with the fiber cell's peak absorption. The initial coating configuration is refined by varying the individual layer thicknesses in an iterative process to maximize both transmission on-resonance and reflectivity off-resonance with the fiber cell's peak absorption. The coatings are applied around the fiber OPV cell on top of a thick transparent coating (greater than 100 nm) that reduces light coherence to minimize parasitic interference effects. The coatings consist of a two alternating materials having refractive index values of n_{H}=2.2 and n_{L}=1.35, values common in optical coating design. For simplicity, the refractive indices of both the thick transparent coating (e.g. barrier) between the outer electrode and the DBR stack, as well as the clear matrix surrounding the coated fibers, are assumed to be the same as air (i.e. n=1). This assumption is made based on the likelihood that the fiber array will be embedded in a clear polymer or glass matrix that has an index nearly identical to that of a typical barrier material (e.g. n=1.4), leading to a conserved diffraction angle. Using n=1 instead also conserves the diffraction angle but simplifies the model. An anti-reflecting coating (ARC) at the surface of the clear matrix holding the fibers will minimize any differences associated with moving away from the n=1 assumption. ARCs on glass have been designed with reflectivity below 1% over the visible spectrum and for a large range of incident angles. In addition, while a host matrix with n=1.4 would require a DBR redesign, this refractive index falls between the values for the DBR coating materials, reducing the optical impedance and improving the coating's performance.

In the next two sections we apply this modeling to multi-fiber OPV cell arrays 10. We first consider the performance of arrays using only one OPV cell structure. The use of multiple spectrally tuned OPV cells are then employed within the fiber matrix to maximize performance across the incident solar spectrum.

### IV. DESIGN OF A MULTI-FIBER OPV ARRAY

To investigate the performance of this design concept we begin by looking at a single OPV cell 20 in a planar configuration, then map its performance onto a single fiber, followed by mapping the performance of a fiber to a row of fibers, and finally consider multiple rows of fibers, illustrated in FIGS. 2a-2d.

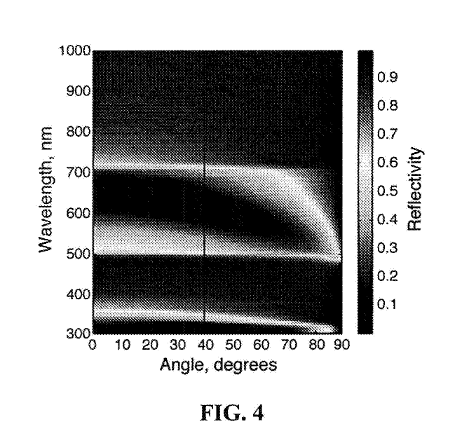

Single Fiber Architecture: The performance of an OPV cell with a single absorption layer that absorbs between approximately 500-700 nm is chosen. Over this wavelength range, the power conversion efficiency is maximized by calculating the trade-off between current (limited by the solar photon flux density at each wavelength) and V_{OC} (defined as a constant that depends only on the chosen optical band gap of the absorption layer, minus, nominally, a minimum feasible exciton binding energy). Using the modeling described herein, the planar OPV cell structure resonant with the 500-700 nm band of incident light which maximizes j_{SC} consists of a 10 nm Ag electrode followed by a 52 nm optical spacer, 15 nm absorption layer, 52 nm exciton blocking layer, and finally a 100 nm Ag back contact. For this device, an optical bandpass filter is not applied. Under AM1.5G illumination, the OPV cell is predicted to have a short circuit current, j_{SC}=8.2 mA/cm². Combining this with a FF=0.7, and a V_{OC} determined to be 1.37 V results in a power conversion efficiency, n=7.86%. Applying this structure to a fiber geometry results in a j_{SC}=7.8 mA/cm²; the reduction in j_{SC} relative to the planar analogue is due to increased reflection at oblique incident angles on the fiber surface, as shown in FIG. 4. For comparison, a planar OPV cell with a 200 nm ITO electrode with optimized layer thicknesses is predicted to have j_{SC}=6.9 mA/cm² and n=6.6%.

Planar Array of Fibers: To capture a portion of the reflected light, the fibers can be placed adjacent to one another, as might be encountered, for example, in a woven textile. A row of adjacent fibers, illustrated in FIG. 2c; based on the ray-tracing model described herein, this array is predicted to have a j_{SC}=8.9 mA/cm², overcoming the losses associated with going to the fiber geometry for normal illumination, and outperforming the planar cell. (Note that in one aspect the linear fiber array is similar to the V-shape reflective tandem OPV cells discussed earlier.)

While a single row of fibers can increase the photocurrent substantially (˜14% over a single fiber OPV cell, and 8.5% over a planar cell), much of the light initially reflected off the fiber surface is not trapped. In appropriately configured multi-row (3-dimensionally distributed) fiber OPV bundles, however, a majority of light rays that enter the fiber matrix bounce between the constituent fibers many times.

Volumetric Array of Fibers: We consider multi-row fiber arrays, varying the depth from 1 to 20 rows. Due to improved packing, performance predicted by ray tracing models was generally best for fibers that were placed in a repeating “slant” arrangement (see FIGS. 5a-5d) over that of a V- or W-shaped arrangement. For each set of rows, the distance between fibers in a slant arrangement was varied spatially both vertically and horizontally to maximize j_{SC}. The geometries of the best-performing bundles for 1, 2, 3 and 10 rows are given in FIGS. 5a-5d, with the performance given in FIG. 6. For the optimized 10-row system, we observed a 36% improvement over the single fiber cell. As expected, there are diminishing returns with increasing the number of rows; at 10 rows, absorption of light over the wavelength range corresponding to the spectrum of the absorption layer exceeds 90%.

With continued reference to FIG. 6, the performance of a planar heterojunction copper phthalocyanine (CuPc)—C₆₀ cell having a thin semitransparent Ag metal electrode is provided. The device structure consists of 10 nm Ag, 10 nm bathocuproine (BCP), 30 nm C₆₀, 25 nm CuPc, 8 nm MoO₃, and 100 nm Ag. The exciton diffusion length was set to 8 nm in CuPc and 20 n in C₆₀, values in agreement with those measured in literature. The device model used here has been shown to accurately predict the performance of this planar heterojunction PV cell. Comparatively, this small molecule OPV cell and the simplified cell initially described are similarly designed with metal electrodes and optical spacers sandwiching the absorption layer(s). The cavities in both cells are tuned for optimal photocurrent generation over a similar bandwidth, and with multiple fiber rows the incident light absorption is maximized. Consequently, the performance between the small molecule planar heterojunction and the simplified single cell design compare well, suggesting the simplified fiber design is a valid estimate of expected OPV performance.

### V. USING MULTIPLE COLOR-TUNED FIBER OPV CELLS TO BUILD AN EFFICIENT BROAD-BAND ARRAY

To increase the efficiency of the multi-fiber OPV system further, a set of spectrally-tuned PV cells are employed in volumetric arrays. The individual OPV cells on fibers retain the same basic structure (i.e. metal-organic-metal), but the thickness of the absorber and other layers are modified to tune the optical microcavity and maximize the photocurrent of an individual fiber device over a specific spectral band. Furthermore, a band-pass optical filter is added (as discussed herein) to efficiently reflect off-resonant wavelengths while remaining transparent for on-resonance wavelengths. These coatings are uniquely designed for each type of spectrally-tuned OPV cell. The fiber arrays incorporate wavelength selective dispersion by virtue of their geometry and the DBR coating, such that incident light is effectively sorted among the sub-cells—a ray of particular wavelength bounces between the constituent fibers until it encounters (and is absorbed by) a complementary tuned fiber OPV cell.

As previously mentioned, in some embodiments, each fiber PV cell can be optimized to have high efficiency over a 200 nm spectral band, with the target spectral band and layer thicknesses of the sub-cells for the range of fiber types provided in Table 1.

TABLE 1
Optical absorption band, expected V_{oc}, and device structure of the fiber
sub-cells used in the multi-fiber tandem OPV cells modeled in FIG. 4*

| No. | Sub-cell | Absorption band, nm | V_{oc}, V | t_{Spacer}, nm | t_{Abz}, nm |
|---|---|---|---|---|---|
| 1 | i | 501-700 | 1.37 | 52 | 15 |
| 2 | i | 450-650 | 1.51 | 44 | 15 |
| | ii | 550-850 | 1.06 | 72.5 | 10 |
| 3 | i | 350-550 | 1.86 | 31 | 12.5 |
| | ii | 550-750 | 1.25 | 55 | 12.5 |
| | iii | 750-950 | 0.91 | 87.5 | 10 |
| 4 | i | 300-500 | 2.08 | 25 | 15 |
| | ii | 365-665 | 1.47 | 45 | 15 |
| | iii | 630-830 | 1.09 | 70 | 12.5 |
| | iv | 800-1000 | 0.84 | 92.5 | 10 |

*The Number column indicates the number of sub-cells for the fiber bundles, the optical spacers above and below the absorption layer are set to the same thickness (t_{Spacer}) for design simplicity, and t_{Abz} is the thickness of the absorption layer.

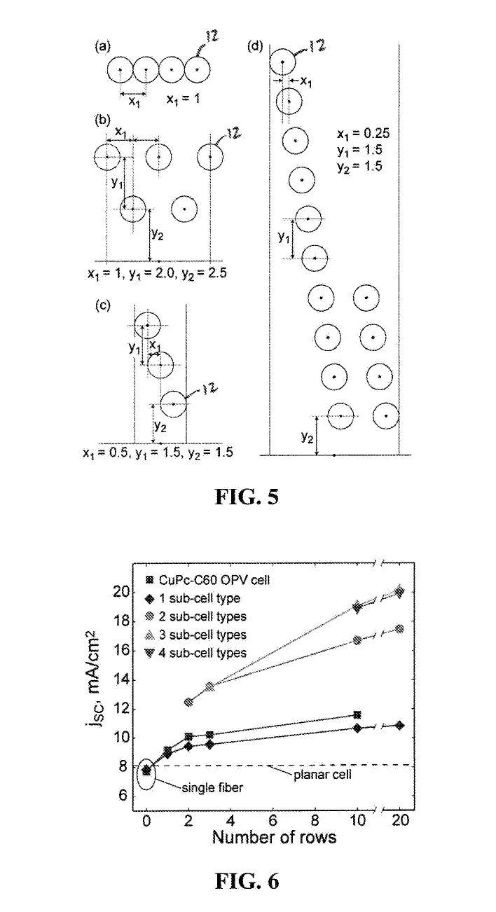

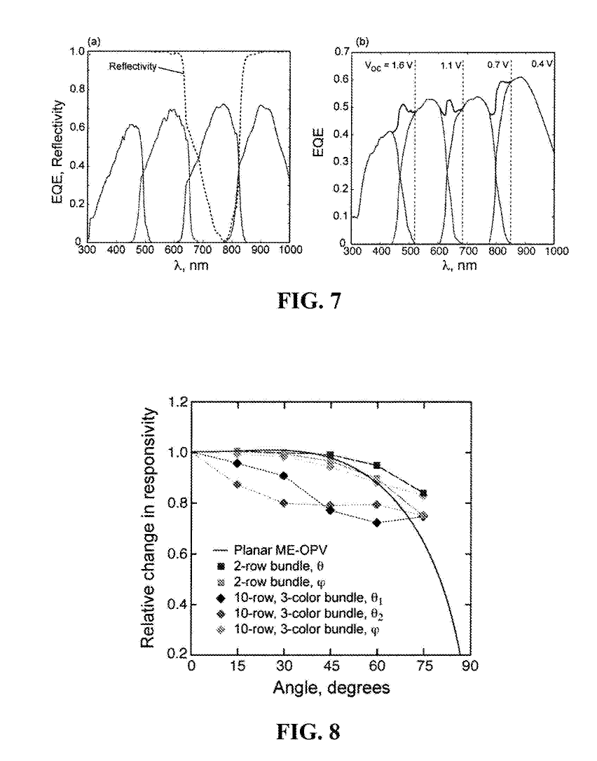

The fiber spatial orientation is the same as the single cell designs (given in FIG. 5) while the color-tuned cell placement is varied within the fiber matrix to maximize performance. A complete optimization of color-tuned cell placement was not performed; however, the best performance was generally observed when the color-tuned cells were similar in number and evenly spaced. For the multi-color fiber systems, light trapping is slightly reduced due to the increased number of reflections before capture, yet there is a substantial gain in the spectral band of light capture. The color-tuned external quantum efficiency of the individual planar cells, along with the external quantum efficiencies of a 10-row, 4-color fiber system is given in FIG. 7a and FIG. 7b, respectively. The reflectivity of the sub-cell tuned between 630-830 nm is also provided as an example of performance typical for the filter-OPV cell designs with high off-resonance reflectivity and high on-resonance absorption. Under the assumption that the absorber layer only absorbs over a 200 nm bandwidth, the microcavity OPV cells will inherently have a high degree of reflectivity off-resonance. However, the filters will be important in mitigating the off-resonant parasitic absorption generally observed in the layers of the OPV cells.

The foregoing analysis predicts the array current. To predict the power conversion efficiency, we place the individual fiber cells in electrical series and/or parallel to match current and voltage intensity and thus each fiber in depth will have a unique maximum power point. However, we expect that the fiber with the same relative coordinate in adjacent unit cells will have the same current-voltage output. These cells can be added in parallel to sum the current without voltage losses. As the external wiring runs down the composite, when current is matched between the multi-cell parallel wiring, the circuit can be combined in series to sum voltage without current losses. The open circuit voltage of each 4 sub-cell design is given in FIG. 7b, and as stated above the fill factor is assumed to be 0.7. Under these assumptions, the power conversion efficiency of the 4 color-tuned sub cell 10-row design is predicted to be 17.0%.

Performance At Different Angles of Illumination: It is also important to consider the performance of these new reflective/inherently dispersive tandem architectures with illumination angle, shown in FIG. 8. Here, the responsivity of a planar microcavity OPV cell tuned between 500-700 nm is given along with a 2-row fiber bundle with the same OPV cell design. It is observed that at low off-normal incident angles (relative to the plane of the fiber array), the responsivity is similar; however, at very large incident angles the bundle system will outperform its planar counterpart. Also given in FIG. 8, is the performance of the 10-row, 3-color tuned fiber OPV bundle. For this system, the specific symmetry of the “repeat unit” of the bundle results in a non-trivial dependence of efficiency on the 3-primary incident angle vectors. The results also indicate that while the 3-row bundle performance for a wide range of longitudinal incident angles (φ). is similar to the 2-row bundle, increasing the other incident angles results in a faster roll-off in efficiency. This highlights the importance of the interplay of illumination angle and array symmetry in the overall system design and optimization.

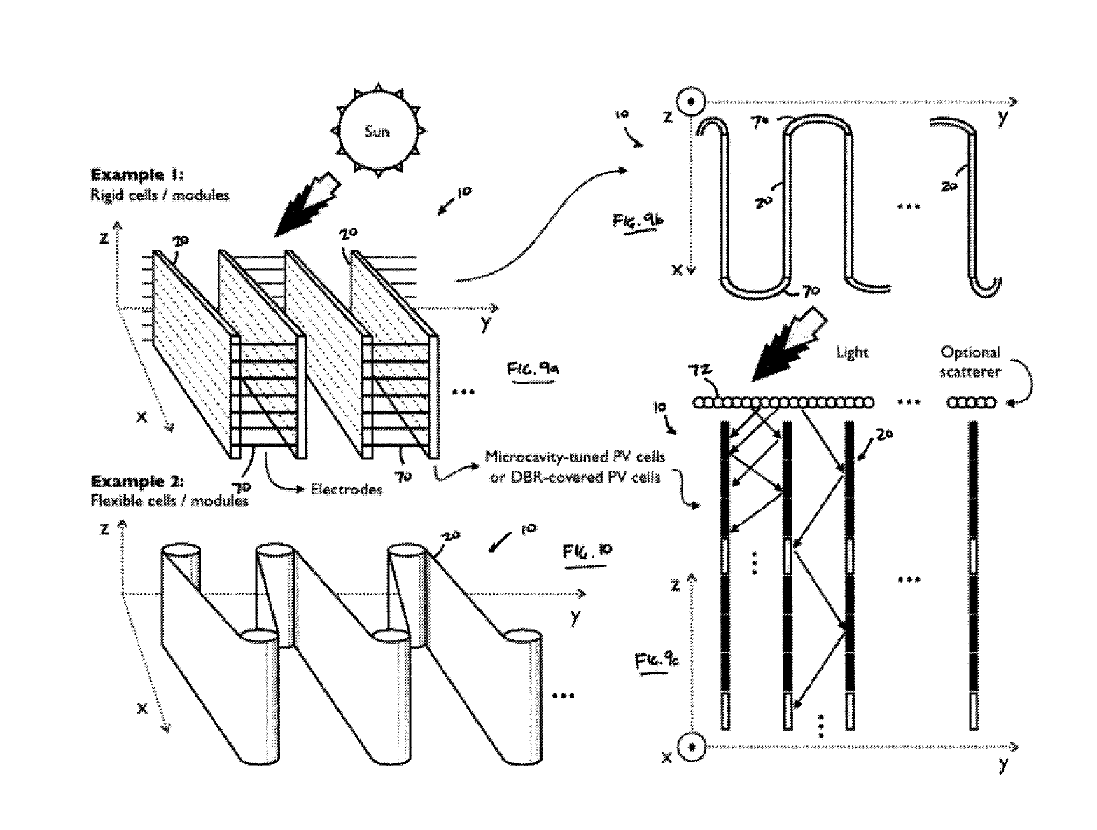

Alternative Configurations: It should be appreciated that the principles of the present teachings can be employed in a wide range of configurations, including rigid solar cells and/or modules, such as those illustrated in FIG. 9a, or flexible solar cells and/or modules, such as those illustrated in FIG. 10. With particular reference to FIGS. 9a and 9b, it can be seen that each of the solar cells 20 can be electrically coupled along electrical connections 70 (such as, but not limited to, wires, paths, and the like). These electrical connections 70 can extend in a serpentine configuration (i.e. electrically coupled in series) or in a ladder configuration (i.e. electrically coupled in parallel). With particular reference to FIG. 9c, it can be seen that the system of the present teachings can defining a plurality of receptor panels, denoted by varying colors or shades of gray, for receiving light. Moreover, the system of the present teachings may further employ one or more optional scatterers 72 for diffusing light.

### VI. CONCLUSIONS

To practically implement a multi-row fiber bundle, it is necessary to hold the fibers in place. This can be accomplished by placing the fibers in a transparent plastic or glass host. This will change the optics at the air-host and host-fiber interfaces, but should not modify the overall efficiency substantially. In addition, bus-lines will be required to transport charge efficiently down long lengths of fiber. The bus-lines can be placed as metal strips underneath each fiber and will also act as light scattering sources in the ray-tracing program. In the models, the fiber bundles are observed to be insensitive to exact geometry, suggesting that the implementation of bus-lines will not substantially alter device performance.

The fiber bundles increase the solar cell surface area compared to a planar cell equivalent. By using low-cost materials the cost of the fiber-based tandem can be kept low, however, it will reduce the illumination intensity of a given area of solar cell potentially affecting device performance. A row of fibers has about 3 times more surface area than planar counterpart when lined up in a row. The 10-row deep fiber design in FIG. 5 has approximately 14 times more surface area. In a simple analysis, the surface of a given fiber sees 1/14 AM1.5 illumination intensity. For organic solar cells, the performance will illumination intensity is not a constant, but is not necessarily optimal at 1-sun. We believe that under this lower intensity, the OPV cells can continue to perform efficiently, and there is some evidence that efficiency of some organic solar cells may even increase at lower illumination intensity (Wei, et al., Adv. Energy Mater. DOI: 10.1002/aenm.201100045). Furthermore, if you take the color-tuned OPV cells, the portion of light intensity that is decreased depends on the number of spectrally tuned cells. For example, for a 3-color tuned OPV cell bundle, the increase in surface for the relevant spectral band is reduced by a 3rd. Taking this into consideration, the 10-row bundle will see a reduced intensity per unit surface area of 3/14 or approximately 20%.

An individual fiber OPV cell has been shown to be less efficient than its planar counterpart. However, simply placing fibers adjacent to one another overcomes the losses through improved light trapping. Placing the fiber cells in a 3-dimensionally distributed array, matrix, or bundle configuration leads to further enhancements in light trapping, resulting in an external quantum efficiency of the PV cell approaching the internal quantum efficiency. By adding sub-cells that are tuned to efficiently convert light over a specific portion of the solar spectrum, the fiber system that efficiently traps light also acts as a built-in dispersion element, matching incident wavelengths of light to a complementary OPV cell. By virtue of optical microcavity design utilizing metallic electrodes and dielectric coatings, the opposing requirements of electrode transparency and conductivity can be decoupled to an extent. Here we have used a combination of optical and transport models to show that color-tuned OPV cells in a fiber matrix can lead to power conversion efficiencies over 17%, assuming modest absorption coefficients, metallic electrodes, and conservative assumptions regarding the fill factor. Through improved light trapping, broadband sensitivity, and output voltage optimization, this efficiency can be doubled over what is predicted for an optimized single junction cell having similar intrinsic properties. Additionally, improvements in the performance of single junction OPV cells will lead to improved performance of the fiber OPV tandem design.

The OPV device designs based on the reflective tandem concept, and fiber-based sub-cells offer several potentially powerful advantages over conventional planar stacked tandem photovoltaic devices. For example, electrical interconnections can be made with much greater latitude for current and voltage matching, in contrast to series-connected tandem cells. Furthermore, spatially distributed fibers can be placed into an inert matrix material that prevents the diffusion of oxygen and moisture, and offer considerable protection from mechanical damage. Finally, the overall concept of a reflective, inherently dispersive tandem architecture involving volumetrically distributed sub-cells potentially can be applied to other sub-cell shaped and material systems, including inorganic PV cells, and/or combinations of organic and inorganic sub-cells.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed is:

1. A solar cell system comprising:
a plurality of fiber-based photovoltaic cells, at least a first of said plurality of fiber-based photovoltaic cells being tailored for power conversion efficiency within a first predetermined band of incident solar spectrum, at least a second of said plurality of fiber-based photovoltaic cells being tailored for power conversion efficiency within a second predetermined band of incident solar spectrum, said first predetermined band being different than said second predetermined band, said plurality of fiber-based photovoltaic cells being disposed in an array defining a high external quantum efficiency over a visible spectrum.

2. The solar cell system according to claim 1 wherein at least one of said plurality of fiber-based photovoltaic cells comprises:
a fiber substrate;
a first optical spacer disposed about said fiber substrate;
an active absorbing layer disposed about said first optical spacer; and
a second optical spacer disposed about said active absorbing layer.

3. The solar cell system according to claim 1 wherein at least one of said plurality of fiber-based photovoltaic cells comprises:
a fiber substrate;
an optically thick silver electrode disposed about said fiber substrate;
an exciton blocking layer disposed about said optically thick silver electrode;
an active absorbing layer disposed about said exciton blocking layer;
a charge transport layer disposed about said active absorbing layer; and
a semitransparent silver cathode disposed about said charge transport layer.

4. The solar cell system according to claim 1 wherein said plurality of fiber-based photovoltaic cells are oriented generally in 3-dimensions, distributed over a region of space greater in volume than a solid volume of the plurality of fiber-based photovoltaic cells alone, thereby defining gaps between each of said plurality of fiber-based photovoltaic cells.

5. The solar cell system according to claim 1 wherein said first of said plurality of fiber-based photovoltaic cells is configured to reflect off-resonance spectral components.

6. The solar cell system according to claim 1 wherein said plurality of fiber-based photovoltaic cells are arranged to form a 3-dimensional array.

7. The solar cell system according to claim 1 wherein said plurality of fiber-based photovoltaic cells are stacked to form a 3-dimensional array.

8. The solar cell system according to claim 1 wherein said plurality of fiber-based photovoltaic cells are woven to form a 3-dimensional array.

9. The solar cell system according to claim 1 wherein said plurality of fiber-based photovoltaic cells is embedded in a polymer matrix.

10. The solar cell system according to claim 1 wherein at least some of said plurality of fiber-based photovoltaic cells are non-circular in cross-section.

11. A solar cell system comprising:
a plurality of planar solar cells being made of an organic or inorganic semiconductor-based material, at least a first of said plurality of planar solar cells being tailored for power conversion efficiency within a first predetermined band of incident solar spectrum, at least a second of said plurality of planar solar cells being tailored for power conversion efficiency within a second predetermined band of incident solar spectrum, said first predetermined band being different than said second predetermined band, said plurality of planar solar cells being disposed in an array defining a high external quantum efficiency over a visible spectrum.

12. The solar cell system according to claim 11 wherein at least one of said plurality of planar solar cells comprises:
a substrate;
a first optical spacer disposed on said substrate;
an active absorbing layer disposed on said first optical spacer; and
a second optical spacer disposed on said active absorbing layer.

13. The solar cell system according to claim 11 wherein at least one of said plurality of planar solar cells comprises:
a substrate;
an optically thick silver electrode disposed on said substrate;
an exciton blocking layer disposed on said optically thick silver electrode;
an active absorbing layer disposed on said exciton blocking layer;
a charge transport layer disposed on said active absorbing layer; and
a semitransparent silver cathode disposed on said charge transport layer.

14. The solar cell system according to claim 11 wherein said plurality of planar solar cells are arranged to form a 3-dimensional array.

15. The solar cell system according to claim 11 wherein said plurality of planar solar cells are stacked to form a 3-dimensional array.

16. The solar cell system according to claim 11 wherein said plurality of planar solar cells are woven to form a 3-dimensional array.

17. The solar cell system according to claim 11 wherein said first of said plurality of planar solar cells is configured to reflect off-resonance spectral components.

18. The solar cell system according to claim 11 wherein said plurality of planar solar cells is embedded in a polymer matrix.

19. A broad-band solar cell comprising:
a plurality of sub-cell members each being oriented generally in 3-dimensions, distributed over a region of space greater in volume than a solid volume of the plurality of sub-cell members alone, thereby defining gaps between each of said plurality of sub-cell members.
